(19) United States
(12) Patent Application Publication
(10) Pub. No.: US 2019/0319108 A1
(43) Pub. Date: Oct. 17, 2019

(54) MOS DEVICE WITH STRONG POLARIZATION COUPLING

(71) Applicant: Samsung Electronics Co., LTD., Gyeonggi-do (KR)

(72) Inventors: Jorge A. Kittl, Austin, TX (US); Borna J. Obradovic, Leander, TX (US); Ryan M. Hatcher, Austin, TX (US); Titash Rakshit, Austin, TX (US)

(21) Appl. No.: 16/141,767

(22) Filed: Sep. 25, 2018

Related U.S. Application Data
(60) Provisional application No. 62/658,538, filed on Apr. 16, 2018.

(51) Int. Cl. H01L 29/51; H01L 27/088; H01L 29/66

(52) U.S. Cl. CPC H01L 29/516; H01L 29/6684; H01L 27/088; H01L 29/513

(57) ABSTRACT

A semiconductor device and method for providing a semiconductor device are described. The semiconductor device includes a channel, a gate, and a multilayer gate insulator structure between the gate and the channel. The multilayer gate insulator structure includes at least one ferroelectric layer and at least one dielectric layer. The at least one ferroelectric layer and the at least one dielectric layer share at least one interface and have a strong polarization coupling.

### CROSS-REFERENCE TO RELATED APPLICATIONS

This application claims the benefit of provisional Patent Application Ser. No. 62/658,538, filed Apr. 16, 2018, entitled “A MOS DEVICE WITH STRONG POLARIZATION COUPLING”, assigned to the assignee of the present application, and incorporated herein by reference.

### BACKGROUND

In order to scale MOS devices to smaller nodes, high dielectric constant (high κ) materials may be used in the gate stack. For example, the gate stack may include an interfacial dielectric layer (IL) adjoining the channel and a high κ layer on the IL layer. The combination of the IL and high κ layers have an equivalent oxide thickness (EOT). The EOT is the thickness of a silicon oxide layer that would have the same effect as the combination of the IL and the high κ layer. Current methods for further EOT scaling include changing composition of the IL to increase the κ-value of the IL or engineering the high κ layer to increase its dielectric constant. These approaches have met with limited success. High κ dielectrics have lower barriers for higher dielectric constants, which results in increased leakage. Due to the increase in leakage and degradation of mobility, as well as practical limitations for known insulator stacks, EOT scaling may be problematic.

MOS devices with a ferroelectric layer in the gate stack have also been proposed. Use of a ferroelectric layer might result in sub-60 mV/dec sub-threshold slope, due to transient negative capacitance, which however may not be useful for low power devices due to switching speed limitations and power dissipated in ferroelectric switching. There are also conventional approaches that focus on a capacitance matching condition between the ferroelectric layer and the remainder of the MOS gate capacitance (such as the IL and channel). However, it is not clear from such approaches that the desired effect of a stabilized negative capacitance is realizable or that the MOS device will not suffer from degradation in performance for other reasons, for example if the ferroelectric layer switches during operation.

Accordingly, what is desired is an improved MOS device with lower EOT, that may be scalable to higher areal densities.

### BRIEF DESCRIPTION OF SEVERAL VIEWS OF THE DRAWINGS

FIGS. 1A and 1B are diagrams depicting an exemplary embodiment of a semiconductor device including a multilayer gate insulator structure having a strong polarization coupling.

FIG. 2 is a diagram depicting another exemplary embodiment of a semiconductor device including a multilayer gate insulator structure having a strong polarization coupling.

FIG. 3 depicts an exemplary embodiment of a portion of a multilayer gate insulator structure having a strong polarization coupling.

FIG. 4 depicts another exemplary embodiment of a portion of multilayer gate insulator structure having a strong polarization coupling.

FIG. 5 depicts another exemplary embodiment of a portion of multilayer gate insulator structure having a strong polarization coupling.

FIG. 6 is a flow chart depicting an exemplary embodiment of a method for providing a semiconductor device including a multilayer gate insulator structure having a strong polarization coupling.

FIG. 7 is a flow chart depicting an exemplary embodiment of a method for providing a multilayer gate insulator structure having a strong polarization coupling.

### DETAILED DESCRIPTION OF THE INVENTION

The exemplary embodiments relate to semiconductor devices having a gate stack including at least one ferroelectric layer and at least one dielectric layer having a strong polarization coupling. The following description is presented to enable one of ordinary skill in the art to make and use the invention and is provided in the context of a patent application and its requirements. Various modifications to the exemplary embodiments and the generic principles and features described herein will be readily apparent. The exemplary embodiments are mainly described in terms of particular methods and systems provided in particular implementations. However, the methods and systems will operate effectively in other implementations.

Phrases such as “exemplary embodiment”, “one embodiment” and “another embodiment” may refer to the same or different embodiments as well as to multiple embodiments. The embodiments will be described with respect to systems and/or devices having certain components. However, the systems and/or devices may include more or fewer components than those shown, and variations in the arrangement and type of the components may be made without departing from the scope of the invention. The exemplary embodiments will also be described in the context of particular methods having certain steps. However, the method and system operate effectively for other methods having different and/or additional steps and steps in different orders that are not inconsistent with the exemplary embodiments. Thus, the present invention is not intended to be limited to the embodiments shown, but is to be accorded the widest scope consistent with the principles and features described herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which this invention belongs. It is noted that the use of any and all examples, or exemplary terms provided herein is intended merely to better illuminate the invention and is not a limitation on the scope of the invention unless otherwise specified. Further, unless defined otherwise, all terms defined in generally used dictionaries may not be overly interpreted.

A semiconductor device and method for providing a semiconductor device are described. The semiconductor device includes a channel, a gate, and a multilayer gate insulator structure between the gate and the channel. The multilayer gate insulator structure includes at least one ferroelectric layer and at least one dielectric layer. The ferroelectric layer(s) and the dielectric layer(s) share interface(s) and have a strong polarization coupling.

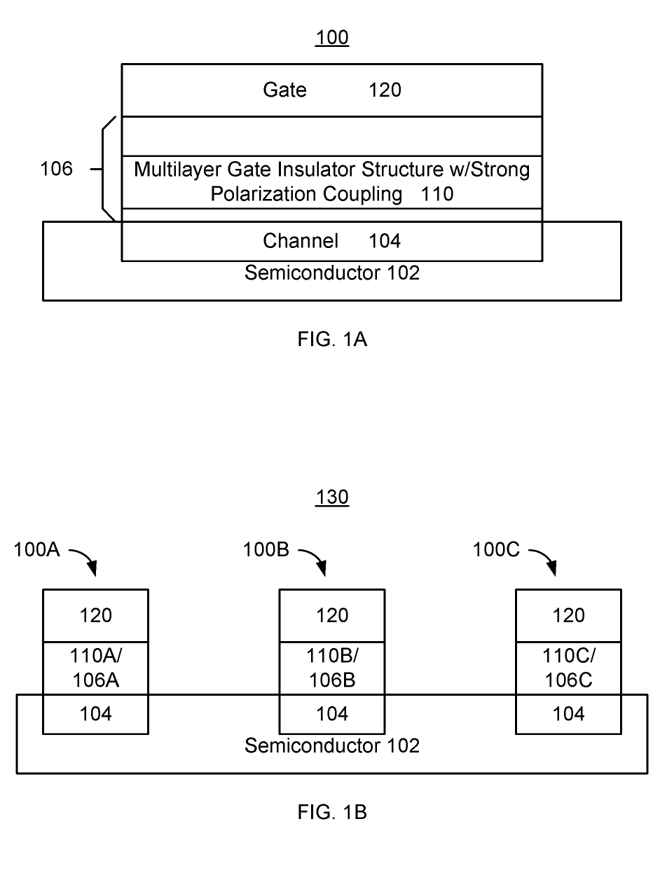

FIGS. 1A and 1B are diagrams depicting an exemplary embodiment of a semiconductor device 100 including a multilayer gate insulator structure having a strong polarization coupling and multiple such semiconductor devices 100A, 100B and 100C integrated into an array 130. For simplicity, only a portion of the semiconductor devices 100 and 130 are shown and FIGS. 1A-1B are not to scale. The semiconductor device 100 may be a transistor such as a metal-oxide-semiconductor (MOS) transistor.

The semiconductor device 100 is formed on a semiconductor substrate 102 and includes at least a channel 104, a gate dielectric structure 106 and a gate 120. The gate stack for the semiconductor device 100 may include structures 106 and 120. A source (not explicitly shown), a drain (not explicitly shown) and/or other components may also be included. The gate dielectric structure 106 includes a multilayer gate insulator structure 110. In some embodiments, the gate dielectric structure 106 is formed only of the multilayer gate insulator structure 110. In other embodiments, additional layers may be included. The semiconductor device 100 shown is a planar device. However, other geometries including but not limited to a finFET and a gate-all-around device may be used for the semiconductor device 100. The gate 120 and channel may be made of known materials. For example, the channel may include at least one of Si, a SiGe alloy, at least one III-V material and at least one transition metal di-chalcogenide compound. The gate 120 may include material(s) such as strontium ruthenate oxide (SRO) and/or TiN.

The multilayer gate insulator structure 110 includes at least one ferroelectric layer and at least one dielectric layer. For example, the multilayer gate insulator structure may be a bilayer consisting of a single dielectric layer and a single ferroelectric layer. In other embodiments, the multilayer gate insulator structure 110 may include three or more layers. In such embodiments, the ferroelectric layer(s) and dielectric layer(s) are interleaved. The ferroelectric layer(s) and dielectric layer(s) share interface(s). The dielectric layer closest to the channel 104 may be an interfacial dielectric layer that also shares another interface with the channel 104. In other embodiments, the ferroelectric layer might be placed closer to (and may share another interface with) the channel.

The ferroelectric layer(s) and dielectric layer(s) have a strong polarization coupling. As used herein, polarization refers to the component of the electrical polarization near the interface and perpendicular to the interface. A strong polarization coupling between the ferroelectric and dielectric layers is such that the component of the electrical polarization of the ferroelectric layer perpendicular to and near the interface is strongly coupled to the electrical polarization of the dielectric layer perpendicular to and near the interface. In some embodiments, this accomplished by forming the ferroelectric layer epitaxially on the dielectric layer. In some embodiments, a strong polarization coupling between the ferroelectric layer(s) and the dielectric layer(s) is such that the electrical polarization(s) of the ferroelectric layer(s) and the electrical polarization(s) of the dielectric layer(s) are within twenty percent of each other. Again, these electrical polarizations are the components that are perpendicular to and close to the interface. In some such embodiments, the polarizations of the layers are within ten percent of each other. In other embodiments, the polarizations of the layers are within two percent of each other. Because of the strong polarization coupling, one or more of the ferroelectric layers in the structure 110 may acts as a dielectric at small polarizations. Consequently, the ferroelectric-dielectric combination may behave as a high-k dielectric with higher-k than the dielectric layer alone.

FIG. 1B depicts semiconductor devices 100A, 100B and 100C (collectively semiconductor devices 100) integrated into a device 130. Although only three semiconductor devices 100 are shown, typically a different (e.g. larger) number of devices are incorporated into a single semiconductor device 130. Because each may be different, each semiconductor device 100A, 100B and 100C is labeled differently. Each semiconductor device is analogous to the semiconductor device 100 and includes components that are analogous to those described with respect to FIG. 1A. Each semiconductor device 100A, 100B and 100C includes a channel 104; a gate dielectric structure 106A, 106B and 106C; and a gate 120 that are analogous to the channel 104, gate dielectric structure 106 and gate 120 of FIG. 1A. Each of the semiconductor devices 100 may include other components such as a source and drain that are not shown for clarity. The gate dielectric structures 106A, 106B and 106C include or consist of multilayer gate insulator structures 110A, 110B and 110C, respectively, that are analogous to multilayer gate insulator structure 110. The multilayer gate insulator structures 110A, 110B and 110C thus include ferroelectric layer(s) and dielectric layer(s) that share interface(s) and have polarizations that are strongly coupled. In some embodiments, the semiconductor devices 100A, 100B and 100C are the same. Thus, the multilayer gate insulator structures 110A, 110B and 110C may be formed of the same materials, have the same number of layers and be substantially the same. In other embodiments, however, the multilayer gate insulator structures 110A, 110B and 110C may be different.

The multilayer gate insulator structures 110, 110A, 110B and/or 110C have a strong polarization coupling between at least some of the dielectric layer(s) and ferroelectric layer(s). This allows such dielectric and ferroelectric layers to function as a very high κ dielectric, avoiding hysteresis in the ferroelectric layer. Use of the multilayer gate insulator structures 110, 110A, 110B and/or 110C may allow very high κ values with little low leakage for the gate stacks of semiconductor devices 100, 100A, 100B and/or 100C. Thus, very low EOT and scaling to smaller nodes may be improved.

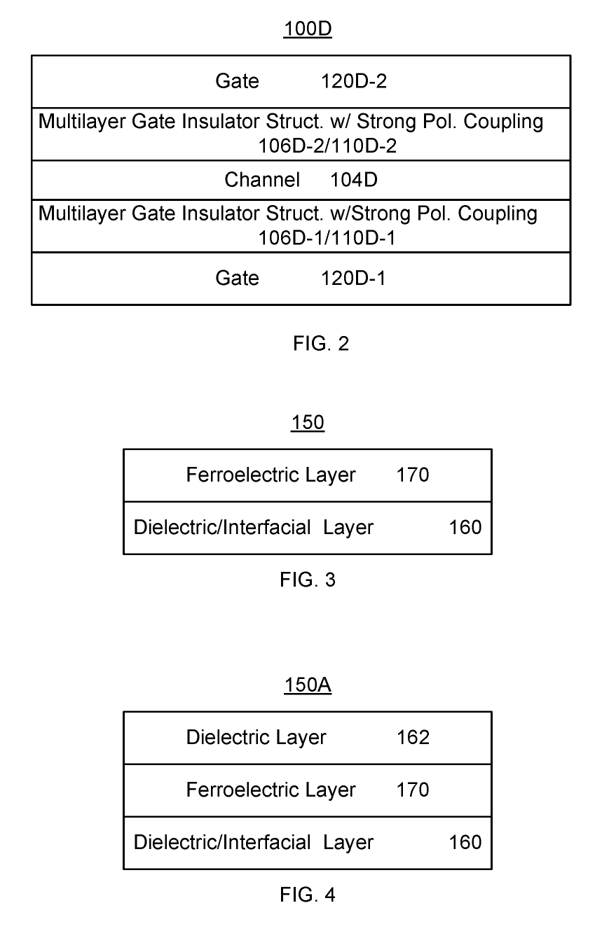

Although planar devices are shown in FIGS. 1A and 1B use of the multilayer gate insulator structures having high polarization couplings is not limited to this geometry. For example, FIG. 2 depicts a semiconductor device 100D having a gate-all-around geometry. The semiconductor device 100D is analogous to the semiconductor devices 100, 100A, 100B and/or 100C. Thus, the semiconductor device 100D includes a channel 104D; gate dielectric structures 106D-1 and 106D-2 and a gate 120 that are analogous to the channel 104; a gate dielectric structure 106, 106A, 106B and 106C; and gate 120 of FIGS. 1A-1B. The semiconductor devices 100D may include other and/or different components such as a source and drain that are not shown for clarity. In the embodiment shown, the gate dielectric structures 106D-1 and 106D-2 consist of a multilayer gate insulator structure 110D-1 and 110D-2. In other embodiments, additional layers might be included. The multilayer gate insulator structures 110D-1 and 110D-2 are analogous to the multilayer gate insulator structures 110, 110A, 110B and/or 110C. Thus, the multilayer gate insulator structures 110D-1 and 110D-2 each includes ferroelectric layer(s) and dielectric layer(s) that share interface(s) and have polarizations that are strongly coupled. In some embodiments, the gate insulator structures 110D-1 and 110D-2 are the same. In alternate embodiments, however, the gate insulator structures 110D-1 and 110D-2 differ. Consequently, the semiconductor device 100D may share the benefits of the semiconductor device(s) 100, 100A, 100B, 100C and/or 130. Further, nothing prevents the use of other geometries for a semiconductor device incorporating a multilayer gate insulator structure having a strong polarization coupling. For example, a finFET may incorporated such a gate dielectric structure.

FIG. 3 is a diagram depicting an exemplary embodiment of a multilayer gate insulator structure 150 having a strong polarization coupling. The multilayer gate insulator structure 150 may be used as the components 110, 110A, 110B, 110C, 110D and/or an analogous component. The multilayer gate insulator structure 150 includes a dielectric layer 160 and an adjoining ferroelectric layer 170 that share an interface. In some embodiments, the dielectric layer 160 is an interfacial layer that shares an interface with and may be epitaxially grown on a channel (not shown in FIG. 3). In some embodiments, the dielectric layer 160 may be a perovskite oxide such as SrTiO₃, Al₂O₃, SiO₂ and SiON may be deposited in step 212. In some embodiments, the ferroelectric layer may include one or more of ferroelectric perovskite(s) (such as Pb(Zr.Ti)O₃ and/or BaTiO₃) and HfO₂-based ferroelectric material(s) (such as Si-doped HfO₂ or ferroelectric (Hf—Zr)O₂).

The layers 160 and 170 have a strong polarization coupling. A strong polarization coupling between the layers 160 and 170 is such that the component of the electrical polarization of the ferroelectric layer 170 perpendicular to and near the interface between the layers 160 and 170 is strongly coupled to the electrical polarization of the dielectric layer 160 perpendicular to and near the interface between the layers 160 and 170. This coupling is believed to originate at the interface of the layers 160 and 170 and thus is of interest close to the interface. In some embodiments, close to (or near) the interface may mean not more than five nanometers from the interface. In some such embodiments, close to the interface is not more than two nanometers from the interface. In some embodiments, near the interface is not more than one nanometer from the interface.

In some embodiments, the strong polarization coupling means that the electrical polarization of the ferroelectric layer 170 and the electrical polarization of the dielectric layer 160 are within twenty percent. This criterion for strong polarization may be expressed as: |P_{FE}−P_{DE}|<0.1|P_{FEMAX}+P_{DEMAX}| or |P_{FE}−P_{DE}|<0.1|P_{FE}+P_{DE}|. P_{FE} is the component of the polarization of the ferroelectric layer 170 normal to the interface and close to the interface with the dielectric layer 160. P_{DE} is the polarization of the dielectric layer 160 normal to the interface and close to the interface with the ferroelectric layer 170. P_{FEMAX} is the absolute value of the maximum component of the polarization of the ferroelectric layer 170 perpendicular and close to the interface during operation. P_{DEMAX} is the absolute value of the maximum component of the polarization of the dielectric layer 160 perpendicular and close to the interface during operation. In some embodiments, the polarizations of the layers 160 and 170 are within ten percent. This may correspond to |P_{FE}−P_{DE}|<0.05|P_{FEMAX}+P_{DEMAX}| or |P_{FE}−P_{DE}|<0.05 |P_{FE}+P_{DE}|. Similarly, the polarizations of the layers 160 and 170 may be within two percent of each other. This condition may be |P_{FE}−P_{DE}|<0.01 |P_{FEMAX}+P_{DEMAX}| or |P_{FE}−P_{DE}|<0.01 |P_{FE}+P_{DE}|. In other embodiments, the polarizations of the layers 160 and 170 may be within one percent of each other. This condition may be expressed as |P_{FE}−P_{DE}|<0.005 |P_{FEMAX}+P_{DEMAX}| or |P_{FE}−P_{DE}|<0.005 |P_{FE}+P_{DE}|.

Alternatively, the strong polarization coupling between the ferroelectric layer 170 and the dielectric layer 160 may be given in terms of the interface polarization coupling constant, λ, the thickness of the dielectric layer 160 (t_{DE}), the thickness of the ferroelectric layer 170 (t_{FE}), and other material parameters. In some embodiments, the combination of the layers 160 and 170 is at least one nanometer thick and not more than thirty nanometers thick. For perovskite systems the combined thickness of the layers 160 and 170 may be at least five and not more than forty nanometers for a SiO₂/ferroelectric Hf-based oxide. In such an embodiment, the SiO₂ dielectric layer 160 might be at least 1.5 nm and not more than 3 nm. For a ferroelectric layer 170 that is a Hf-based oxide, the thickness may be at least 1.5 nm and not more than 6 nm. A ferroelectric Hf-based oxide used in the ferroelectric layer 170 may be a ferroelectric doped-HfO₂ (e.g. doped with Si, Al, Y.) or a ferroelectric (Hf—Zr))O₂ (also called HZO), typically Hf_{0.5}Zr_{0.5}O₂. For example, a strong polarization coupling between the layers 160 and 170 may be such that λ>−α_{FE}*t_{FE}. Alternatively, the condition of strong polarization coupling may be given by λ>|α_{FE}|*t_{FE}, where α_{FE} is a material parameter of the ferroelectric layer, which is defined through an approximation to the energy of the ferroelectric given by the Landau expression:

$${U}_{b}^{ferroelectric} = A [ {d}_{FE} ( \frac{{α}_{FE}}{2} {P}_{FE}^{2} + \frac{{β}_{FE}}{4} {P}_{FE}^{4} + \frac{{γ}_{FE}}{6} {P}_{FE}^{6} ) ]$$

Where α_{FE}<0 and either β_{FE} or γ_{FE} are >0: for materials with second order ferroelectric phase transitions, β_{FE}>0, while materials with first order ferroelectric phase transition may be modelled with β_{FE}<0 and γ_{FE}>0.

In some embodiments, the strong polarization coupling means the overall system energy for the multilayer gate insulator structure 150 is such that the lowest free energy of the combined dielectric and ferroelectric layers 160 and 170 corresponds under operation conditions to a polarization behavior of a dielectric. Stated differently, the electrical polarization of the multilayer gate insulator structure 150 is proportional to the applied electric field with no hysteretic behavior.

This strong polarization coupling is in contrast the use of ferroelectric layers in the gates stacks of most semiconductor devices such as MOS devices. In such conventional MOS devices, there is typically little or no polarization coupling between the layers. At incoherent and/or disordered interfaces, there is no incentive to maintain a matching of the polarizations of the dielectric and ferroelectric layers. Each layer minimizes its free energy independently by adopting its optimal polarization. The same happens in general at incoherent and/or disordered interfaces between a dielectric and a ferroelectric or between a semiconductor and a ferroelectric. In contrast, the strong polarization condition for the multilayer gate insulator structure 150, may be explained as follows. A polarization coupling may exist in epitaxial systems, such as between epitaxial perovskite layers in which one layer is a ferroelectric. In some embodiments, the layers 160 and 170 may fulfill these criteria. The interfacial free energy, f₁, of the interface between two layers 160 and 170 may be expressed as:

Uᵢ=(λ/2)(P₁₀−P₂₀)²

P₁₀ and P₂₀ are the interfacial polarizations (polarizations components normal to the interface, taken close to the interface as described above) of layers 160 and 170 respectively. As discussed above, the parameter λ is the coupling constant describing the strength of the polarization coupling (interaction).

In epitaxial systems in which one or both layers are ferroelectric (and may be piezoelectric), strong interfacial coupling may be present. In these systems, there is a large interface energy penalty to a difference between polarizations at and/or near the interface. When the multilayer gate insulator structure 150 contains thin layers, the interface free energy term may dominate over the volume free energy terms of the layers 160 and 170. Consequently, the multilayer gate insulator structure 150 may adopt a relatively uniform polarization across dissimilar layers. Stated differently, the polarizations may be strongly coupled as described above even though one layer 170 is a ferroelectric and the other layer 160 is not.

To further explain the strong coupling, a simplified analysis for direct contact between a ferroelectric layer 170 and a dielectric layer 160 is described. The multilayer 150 may be used in a MOS device with an area, A, of the gate 120, and thicknesses of the dielectric and ferroelectric layers 160 and 170 of d_{DE} and d_{FE} respectively. The total system energy may be modeled as:

$${U}_{b}^{system} \approx A [ {d}_{DE} ( \frac{{α}_{DE}}{2} {P}_{DE}^{2} ) + {d}_{FE} ( \frac{{α}_{FE}}{2} {P}_{FE}^{2} + \frac{{β}_{FE}}{4} {P}_{FE}^{4} + \frac{{γ}_{FE}}{6} {P}_{FE}^{6} ) + \frac{λ}{2} {( {P}_{DE} - {P}_{FE} )}^{2} ]$$

where λ (>0) is the interface polarization coupling constant describing the strength of the interface polarization coupling, P_{DE} is the polarization of the dielectric layer 160, α_{DE}>0 is a material parameter of the dielectric layer 160, P_{FE} is the polarization of the ferroelectric layer 170, α_{FE},β_{FE} and γ_{FE} are material parameters for the ferroelectric layer 170. In such a case, α_{FE}<0 (for a temperature in which the material used in the layer 170 is in the ferroelectric phase). For materials with second order ferroelectric phase transitions, β_{FE}>0, while materials with first order ferroelectric phase transition may be modelled with β_{FE}<0 and γ_{FE}>0.
At small polarizations:

$${U}_{b}^{system} \approx A [ {d}_{DE} ( \frac{{α}_{DE}}{2} {P}_{DE}^{2} ) + {d}_{FE} ( \frac{{α}_{FE}}{2} {P}_{FE}^{2} ) + \frac{λ}{2} {( {P}_{DE} - {P}_{FE} )}^{2} ]$$

Thus, the condition of strong polarization coupling between the dielectric layer 160 and the ferroelectric layer 170 can be expressed as:

λ>−α_{FE}d_{FE}=|α_{FE}|d_{FE}

In some embodiments,

λ>>−α_{FE}d_{FE}=|α_{FE}|d_{FE}

In some embodiments, >> indicates at least a factor of 5 larger. In other embodiments, >> indicates at least one order of magnitude larger. In some embodiments, >> indicates at least two orders of magnitude larger. In some such embodiments, >> is at least three orders of magnitude larger.

In some embodiments, the following condition is also met:

$${d}_{DE} {α}_{DE} > \vert {α}_{FE} \vert {d}_{FE} \frac{λ}{( λ - \vert {α}_{FE} \vert {d}_{FE} )}$$

In such cases, the ferroelectric layer 170 in the multilayer gate insulator structure 150 behaves like a dielectric. In other words, the ferroelectric layer 170 has an electrical polarization that is proportional to the applied electric field with no hysteretic behavior.

Thus, the strong polarization coupling between the layers 160 and 170 may be expressed in a number of ways. This strong polarization coupling may also result in the multilayer gate insulator structure 150 having an electrical polarization that is proportional to the applied field and which does not exhibit hysteresis despite the presence of the ferroelectric layer 170. Moreover, such a multilayer gate insulator structure 150 may have a very high κ in combination with low leakage. Thus, EOT scaling in semiconductor devices such as MOS devices using the multilayer gate insulator structure 150 may be improved.

The above can be generalized to more complex stacks than bilayers, and to include any interactions with the electrodes. FIG. 4 is a diagram depicting an exemplary embodiment of a multilayer gate insulator structure 150A having a strong polarization coupling. The multilayer gate insulator structure 150A may be used as the components 110, 110A, 1108, 110C, 110D and/or an analogous component. The multilayer gate insulator structure 150A is analogous to the multilayer gate insulator structure 150. Thus, the multilayer gate insulator structure 150A includes a dielectric layer 160 and an adjoining ferroelectric layer 170 that share an interface and which are analogous to the layers 160 and 170 depicted in FIG. 3. In addition, the gate insulator structure 150A includes an additional dielectric layer 162 that also shares an interface with the ferroelectric layer 170. The ferroelectric layer 170 is thus sandwiched between the dielectric layers 160 and 162. The dielectric layers 160 and 162 may be made of the same or different materials.

The layers 160, 170 and 162 have a strong polarization coupling. A strong polarization coupling between the layers 160, 162 and 170 is such that the component of the electrical polarization of the ferroelectric layer 170 perpendicular to and near the interface between the layers 160 and 170 is strongly coupled to the electrical polarization of the dielectric layer 160 perpendicular to and near the interface between the layers 160 and 170. Similarly, the polarization coupling between the layers 162 and 170 is such that the component of the electrical polarization of the ferroelectric layer 170 perpendicular to and near the interface between the layers 162 and 170 is strongly coupled to the electrical polarization of the dielectric layer 162 perpendicular to and near the interface between the layers 162 and 170. Thus, the electrical polarizations of the layers 160, 162 and 170 are within twenty percent. In some embodiments, the polarizations of the layers 160, 162 and 170 are within ten percent. Similarly, the polarizations of the layers 160, 162 and 170 may be within two percent of each other. These conditions may be expressed as above.

Alternatively, the strong polarization coupling between the ferroelectric layer 170 and the dielectric layers 160 and 162 may be expressed in terms of the interface polarization coupling constants for each of the interfaces, λ1 and λ2, the thickness of the ferroelectric layer 170 (t_{FE}), and other material parameters. For example, a strong polarization coupling between the layers 160, 162 and 170 may be expressed as λ1+λ2>−α_{FE}*t_{FE}. Alternatively, this may be viewed as: λ1+λ2>|α_{FE}|*t_{FE}. This may also be expressed as the sum of the thicknesses of the layers. The strong polarization coupling may also be expressed as:

α_{DE}d_{DE}>|α_{FE}|d_{FE}λ/(λ−|α_{FE}|d_{FE})

where d_{FE} is the total thickness of the ferroelectric layer(s), d_{DE} is the total thickness of the dielectric layers and λ an interface polarization coupling constant. The total thickness of the ferroelectric layers is a first sum of the thickness for each ferroelectric layer 170 (in this case the thickness of the single layer). The total thickness of the dielectric layers is a sum of thicknesses for each of the dielectric layers 160 and 162 (t₁₆₀+t₁₆₂). In some embodiments, the strong polarization coupling is such that the polarization of the ferroelectric layer 170 corresponds to that of a dielectric. Stated differently, the electrical polarization of the ferroelectric layer 170 is proportional to the applied electric field with no hysteretic behavior. Such a multilayer gate insulator structure 150A may have a very high κ in combination with low leakage. Thus, EOT scaling in semiconductor devices using the multilayer gate insulator structure 150A may be improved.

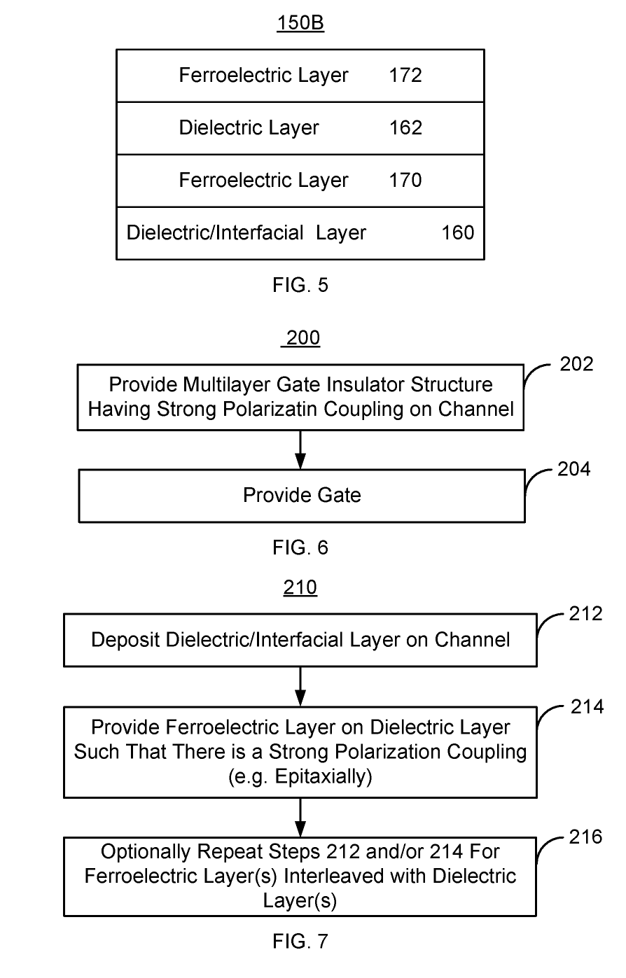

This can be further generalized to another number of dielectric and ferroelectric layers that are interleaved. For example, FIG. 5 is a diagram depicting an exemplary embodiment of a multilayer gate insulator structure 150B having a strong polarization coupling. The multilayer gate insulator structure 150B may be used as the components 110, 110A, 1108, 110C, 110D and/or an analogous component. The multilayer gate insulator structure 150B is analogous to the multilayer gate insulator structure(s) 150 and/or 150A. Thus, the multilayer gate insulator structure 150B includes dielectric layers 160 and 162 and an adjoining ferroelectric layer 170 that share interfaces with the layers 160 and 162. The layers 160 and 162 in FIG. 5 are analogous to the layers 160 and 170 depicted in FIGS. 3-4. In addition, the gate insulator structure 150B includes an additional ferroelectric layer 172 that also shares an interface with the dielectric layer 162. The ferroelectric layer 170 is thus sandwiched between the dielectric layers 160 and 162.

The layers 160, 162, 170 and 172 have a strong polarization coupling. A strong polarization coupling between the layers 160 and 170 is such that the component of the electrical polarization of the ferroelectric layer 170 perpendicular to and near the interface between the layers 160 and 170 is strongly coupled to the electrical polarization of the dielectric layer 160 perpendicular to and near the interface between the layers 160 and 170. The polarization coupling between the layers 162 and 170 is such that the component of the electrical polarization of the ferroelectric layer 170 perpendicular to and near the interface between the layers 162 and 170 is strongly coupled to the electrical polarization of the dielectric layer 162 perpendicular to and near the interface between the layers 162 and 170. Further, the strong polarization coupling between the layers 162 and 172 is such that the component of the electrical polarization of the ferroelectric layer 172 perpendicular to and near the interface between the layers 162 and 172 is strongly coupled to the electrical polarization of the dielectric layer 162 perpendicular to and near the interface between the layers 162 and 172. In an alternate embodiment, not all of the ferroelectric layers exhibit a strong polarization coupling with the adjoining dielectric layer(s). For example, only the layer 172 may be strongly coupled with dielectric layer 162.

Because of the strong polarization coupling, the electrical polarizations of the layers 160, 162, 170 and 172 are within twenty percent. In some embodiments, the polarizations of the layers 160, 162, 170 and 172 are within ten percent. Similarly, the polarizations of the layers 160, 162, 170 and 172 may be within two percent of each other. These conditions may be expressed as above. Alternatively, the strong polarization coupling between the ferroelectric layer 170 and 172 and the dielectric layers 160 and 162 may be expressed in terms of the sum of the thicknesses of the layers. The strong polarization coupling may also be given by:

α_{DE}d_{DE}>|α_{FE}|d_{FE}λ/(λ−|α_{FE}|d_{FE})

where d_{FE} is the total thickness of the ferroelectric layer(s), d_{DE} is the total thickness of the dielectric layers and λ an interface polarization coupling constant. The total thickness of the ferroelectric layers is a first sum of the thickness for each of the ferroelectric layers 170 and 172 (in this case t₁₇₀+t₁₇₂). The total thickness of the dielectric layers is a sum of thicknesses for each of the dielectric layers 160 and 162 (t₁₆₀+t₁₆₂). In an alternate embodiment, the polarization coupling between all of the layers 160, 162, 170 and 172 need not be strong. Instead, the polarization coupling between at least one of the dielectric layers 160 and 162 and at least one of the ferroelectric layers 170 and 172 is strong as defined above. In other embodiments in which the multilayer gate insulator structure has another number of layers, the expression above may be generalized to the other number of layers. In some embodiments, the polarization coupling is such that the polarization of one or both of the ferroelectric layers 170 and 172 corresponds to that of a dielectric. Stated differently, the electrical polarization(s) of the ferroelectric layer 170 and/or the ferroelectric layer 172 is proportional to the applied electric field with no hysteresis. Such a multilayer gate insulator structure 150B may have a very high κ in combination with low leakage. Thus, EOT scaling in semiconductor devices such as MOS devices using the multilayer gate insulator structure 150B may be improved.

FIG. 6 is a flow chart depicting an exemplary embodiment of a method 200 for providing a semiconductor device including a multilayer gate insulating structure having a strong polarization coupling. The method 200 is also described in the context of the semiconductor devices 100 and 100D. However, the method 200 may be used in connection with another semiconductor device. For simplicity, not all steps are shown. Further, the steps may be performed in another order, include substeps and/or be combined. The method 200 is also described in the context of a single semiconductor device being formed. However, it is more typical to form multiple devices substantially simultaneously.

A gate dielectric structure 106/106D is provided on a channel 104, via step 202. Step 202 includes providing the multilayer gate insulator structure 110/110D that has a strong polarization coupling. Thus, step 202 includes providing at least one ferroelectric layer and at least one dielectric layer such that the ferroelectric layer(s) and the dielectric layer(s) share interface(s) and have a strong polarization coupling as defined above. In some embodiments, step 202 consists of providing the multilayer gate insulator structure 110/110D. In other embodiments, additional layers may also be formed.

The gate 120 is provided on the date dielectric structure 106/106D, via step 204. Thus, the multilayer gate insulator structure residing between the gate and the channel. Using the method 200, the semiconductor device(s) 100, 100A, 1008, 100C and/or 100D may be formed. Examples of the gate electrodes for devices may include but are not limited to SRO and TiN. Planar, gate-all-around, finFET and/or other semiconductor devices having a multilayer gate insulating structure with a strong polarization coupling may thus be formed. Consequently, the benefits thereof may be achieved.

FIG. 7 is a flow chart depicting an exemplary embodiment of a method 210 a multilayer gate insulating structure having a strong polarization coupling. The method 210 is also described in the context of the structures 150, 150A, 150B and/or another analogous multilayer gate insulating structure. For simplicity, not all steps are shown. Further, the steps may be performed in another order, include substeps and/or be combined. The method 210 is also described in the context of a single gate insulating structure being formed. However, it is more typical to form multiple devices substantially simultaneously.

The dielectric layer 160 is provided on a channel 104, via step 212. Step 212 thus forms the interfacial layer on the channel. Material(s) such as one or more of a perovskite oxide such as SrTiO₃, Al₂O₃, SiO₂ and SiON may be deposited in step 212.

A ferroelectric layer 170 is deposited on the dielectric layer 160, via step 214. This step is performed such that the layers 160 and 170 have a strong polarization coupling as described above. Step 212 may include epitaxially depositing the ferroelectric layer 170 on the dielectric layer 160. Material(s) such as one or more of ferroelectric perovskite(s) (such as Pb(Zr.Ti)O₃ and/or BaTiO₃) and HfO₂-based ferroelectric material(s) (such as Si-doped HfO₂ or ferroelectric (Hf—Zr)O₂) may be provided in step 214.

Steps 212 and/or 214 are optionally repeated, via step 216. For example, step 212 may be repeated to form dielectric layer 162 of the multilayer gate insulator structure 150A. Steps 212 and 214 may be repeated to form layers 162 and 172 of the multilayer gate insulator structure 150B. Additional layers may also be deposited to provide a structure in which dielectric and ferroelectric layers are interleaved and have a strong polarization coupling. Consequently, the structures 110, 110A, 110B, 110C, 110D, 150, 150A, 150B and/or an analogous structure may be formed and the benefits thereof realized.

The method and system have been described in accordance with the exemplary embodiments shown, and one of ordinary skill in the art will readily recognize that there could be variations to the embodiments, and any variations would be within the spirit and scope of the method and system. Accordingly, many modifications may be made by one of ordinary skill in the art without departing from the spirit and scope of the appended claims.

We claim:

1. A semiconductor device comprising:
a channel;
a multilayer gate insulator structure including at least one ferroelectric layer and at least one dielectric layer, the at least one ferroelectric layer and the at least one dielectric layer sharing at least one interface and having a strong polarization coupling; and
a gate, the multilayer gate insulator structure residing between the gate and the channel.

2. The semiconductor device of claim 1 wherein the at least one ferroelectric layer has a first polarization, the at least one dielectric layer has a second polarization, the strong polarization coupling being such that the first polarization and the second polarization are within twenty percent of each other.

3. The semiconductor device of claim 2 wherein the first polarization and the second polarization are within ten percent of each other.

4. The semiconductor device of claim 2 wherein the first polarization and the second polarization are within two percent of each other.

5. The semiconductor device of claim 1 wherein the at least one ferroelectric layer includes a first ferroelectric layer, the at least one dielectric layer includes a first dielectric layer, the first ferroelectric layer sharing a first interface of the at least one interface with the first dielectric layer, the multilayer gate insulator structure having an interface polarization coupling constant (λ) that is at least one of greater than the negative one multiplied by α_{FE} multiplied by t_{FE}(λ>−α_{FE}t_{FE}) and greater than the absolute value of α_{FE} multiplied by t_{FE} (λ>|α_{FE}*t_{FE}) where α_{FE} is a material parameter of the ferroelectric layer and t_{FE} is a thickness of the ferroelectric layer.

6. The semiconductor device of claim 1 wherein the at least one ferroelectric layer includes a first ferroelectric layer, the at least one dielectric layer includes a first dielectric layer and a second dielectric layer, the first ferroelectric layer sharing a first interface of the at least one interface with the first dielectric layer, the first ferroelectric layer sharing a second interface of the at least one interface with the second dielectric layer, the multilayer gate insulator structure having a first interface polarization coupling constant (λ1) for the first interface and a second interface polarization coupling constant (λ2) for the second interface such that a sum of the first and second interface polarization constants is at least one of greater than the negative one multiplied by α_{FE} multiplied by t_{FE} (λ1+λ2>−α_{FE}*t_{FE}) and greater than the absolute value of α_{FE} multiplied by t_{FE} (λ1+λ2>|α_{FE}*t_{FE}) where α_{FE} is a material parameter of the ferroelectric layer and t_{FE} is a thickness of the ferroelectric layer.

7. The semiconductor device of claim 1 wherein the multilayer gate insulator structure has a total thickness of the at least one ferroelectric layer (d_{FE}), a total thickness of the at least one dielectric layer (d_{DE}), an interface polarization coupling constant (λ), α_{FE} is a material parameter of the at least one ferroelectric layer and a ferroelectric permeability (χ) such that:
α_{DE}d_{DE}>|α_{FE}|d_{FE}λ/(λ−|α_{FE}|d_{FE})
where the total thickness of the at least one ferroelectric layer is a first sum of at least one thickness for each of the at least one ferroelectric layer, the total thickness of the at least one dielectric layer is a second sum of at least one thickness for each of the at least one dielectric layer.

8. The semiconductor device of claim 1 wherein the at least one dielectric layer includes at least one of a perovskite oxide, SrTiO₃, Al₂O₃, SiO₂ and SiON, the at least one ferroelectric layer include at least one of a ferroelectric perovskite, (Pb(Zr.Ti)O₃), BaTiO₃, at least one HfO₂-based ferroelectric material, Si-doped HfO₂ and ferroelectric (Hf—Zr)O₂ the channel includes at least one of Si, a SiGe alloy, at least one III-V material and at least one transition metal di-chalcogenide compound.

9. The semiconductor device of claim 1 wherein the at least one ferroelectric layer is epitaxial to the at least one dielectric layer.

10. The semiconductor device of claim 1, wherein the semiconductor device is selected from a planar device, a finFET and a gate-all-around device.

11. The semiconductor device of claim 1 wherein at least one of the at least one ferroelectric layer has at least one electrical polarization that is free from hysteresis.

12. A semiconductor device comprising:
a plurality of metal-oxide semiconductor (MOS) devices, each of the plurality of MOS devices including at least one channel, at least one multilayer gate insulator structure and at least one gate, the at least one multilayer gate insulator structure including at least one ferroelectric layer and at least one dielectric layer, the at least one ferroelectric layer and the at least one dielectric layer sharing at least one interface and having a strong polarization coupling, the multilayer gate insulator structure residing between the gate and the channel.

13. The semiconductor device of claim 12 wherein the at least one ferroelectric layer has a first polarization, the at least one dielectric layer has a second polarization, the strong polarization coupling being such that the first polarization and the second polarization being within twenty percent of each other.

14. The semiconductor device of claim 13 wherein the first polarization and the second polarization are within ten percent of each other.

15. The semiconductor device of claim 12 wherein the semiconductor device is a metal-oxide semiconductor (MOS) device, the at least one dielectric layer includes at least one of a perovskite oxide, SrTiO₃, Al₂O₃, SiO₂ and SiON, the at least one ferroelectric layer include at least one of a ferroelectric perovskite, (Pb(Zr.Ti)O₃), BaTiO₃, at least one HfO₂-based ferroelectric material, Si-doped HfO₂ and ferroelectric (Hf—Zr)O₂ the channel includes at least one of Si, a SiGe alloy, at least one III-V material and at least one transition metal di-chalcogenide compound.

16. The semiconductor device of claim 1 wherein the at least one ferroelectric layer is epitaxial to the at least one dielectric layer.

17. A method for providing a semiconductor device comprising:
providing a multilayer gate insulator structure on a channel including
providing at least one ferroelectric layer; and
providing at least one dielectric layer such that the at least one ferroelectric layer and the at least one dielectric layer share at least one interface and have a strong polarization coupling; and
providing a gate, the multilayer gate insulator structure residing between the gate and the channel.

18. The method of claim 17 wherein the at least one ferroelectric layer has a first polarization, the at least one dielectric layer has a second polarization, the strong polarization coupling being such that the first polarization and the second polarization are within twenty percent of each other.

19. The method of claim 17 wherein the multilayer gate insulator structure has a total thickness of the at least one ferroelectric layer (d_{FE}), a total thickness of the at least one dielectric layer (d_{DE}), an interface polarization coupling constant (λ), α_{FE} is a material parameter of the at least one ferroelectric layer and a ferroelectric permeability (χ) such that:
α_{DE}d_{DE}>|α_{FE}|d_{FE}λ/(λ−|α_{FE}|d_{FE})
where the total thickness of the at least one ferroelectric layer is a first sum of at least one thickness for each of the at least one ferroelectric layer, the total thickness of the at least one dielectric layer is a second sum of at least one thickness for each of the at least one dielectric layer.
